(19) United States
(12) Patent Application Publication
(10) Pub. No.: US 2026/0026119 A1
(43) Pub. Date: Jan. 22, 2026

(54) SEMICONDUCTOR PACKAGE HAVING A STEPPED MOLDING STRUCTURE

(71) Applicant: SAMSUNG ELECTRONICS CO., LTD., SUWON-SI (KR)

(72) Inventor: KYONGSOON CHO, Suwon-si (KR)

(21) Appl. No.: 19/172,706

(22) Filed: Apr. 8, 2025

(30) Foreign Application Priority Data
Jul. 18, 2024 (KR) 10-2024-0094821

(51) Int. Cl. H10F 39/00

(52) U.S. Cl. CPC H10F 39/804; H10F 39/011; H10F 39/811

(57) ABSTRACT

A semiconductor package includes a semiconductor substrate, an image sensor chip disposed on a first substrate surface of the semiconductor substrate, a cover glass disposed spaced apart from an upper portion of the image sensor chip, a molding structure including a step configured to accommodate the cover glass, wherein a side surface of the cover glass extends above the molding structure, and disposed on the first substrate surface of the semiconductor substrate to surround the image sensor chip, and an adhesive layer disposed at a bottom surface and an inner side surface of the step and configured to fix a lower surface and the side surface of the cover glass to the molding structure.

### CROSS-REFERENCE TO RELATED APPLICATION

This application claims priority under 35 U.S.C. § 119 to Korean Patent Application No. 10-2024-0094821, filed on Jul. 18, 2024, in the Korean Intellectual Property Office, the entire disclosure of which is herein incorporated by reference for all purposes.

### BACKGROUND

### 1. Technical Field

The present disclosure relates to a semiconductor package and a semiconductor package manufacturing method, and more particularly to a semiconductor package having a stepped molding structure.

### 2. Discussion of Related Art

As electronic devices become lighter and more powerful, there is a growing demand for miniaturization and enhanced performance in semiconductor packaging. To achieve smaller, lighter, high-performance, high-capacity, and highly reliable semiconductor packages, ongoing research and development are focusing on semiconductor packages having multi-layered structures in which semiconductor chips are stacked.

### SUMMARY

According to an embodiment, a semiconductor package includes a semiconductor substrate, an image sensor chip disposed on a first substrate surface of the semiconductor substrate, a cover glass disposed spaced apart from an upper portion of the image sensor chip, a molding structure including a step configured to accommodate the cover glass, wherein a side surface of the cover glass extends above the molding structure, and disposed on the first substrate surface of the semiconductor substrate to surround the image sensor chip, and an adhesive layer disposed at a bottom surface and an inner side surface of the step and configured to fix a lower surface and the side surface of the cover glass to the molding structure.

The semiconductor package may further include a conductive wire configured to electrically connect the image sensor chip to the first substrate surface. A redistribution layer (RDL) electrically connected to the conductive wire may be formed in the semiconductor substrate. A connection pad electrically connected to the RDL may be disposed on a second substrate surface of the semiconductor substrate.

A sum of an area of the bottom surface of the step and an area of the inner side surface of the step may be greater than a cross-sectional area of the molding structure in a state in which the first substrate surface is viewed.

An area of the inner side surface of the step may be greater than an area of an uppermost surface of the molding structure.

An upper edge portion the cover glass has a bevel shape or a rounded shape.

The molding structure may include a wall disposed on the first substrate surface and a protrusion protruding upward from an outer edge portion of the wall. The step may be formed by an upper surface of the wall and an inner side surface of the protrusion.

The molding structure may include a storage space formed in a shape recessed in at least a portion of the protrusion. A bottom surface of the storage space may be on a same plane as the upper surface of the wall.

The molding structure may include a plurality of straight regions and a plurality of corner regions in a plan view. The storage space may be formed on at least one straight region of the plurality of straight regions.

The storage space may be formed at a center portion of the at least one straight region of the plurality of straight regions.

The storage space may not be formed in the plurality of corner regions.

The molding structure may further include a storage space in which an extra adhesive material of an adhesive material forming the adhesive layer remains, wherein the extra adhesive material extends from an area between the step and the cover glass.

A width of the cover glass may be less than a width of a space between inner side surfaces of steps facing each other in a plan view.

The cover glass may include a main glass portion supported by the step and a lower glass portion protruding downward from the main glass portion toward the first substrate surface and fixed to an inner side surface of the molding structure by the adhesive layer.

The cover glass may include a main glass portion supported by the step and a side glass portion protruding upwardly and outwardly from an upper side of a side surface of the main glass portion and fixed to an uppermost surface of the molding structure by the adhesive layer.

The semiconductor package may further include a reinforcing body disposed at a position overlapping the molding structure and the cover glass in a state in which the first substrate surface is viewed.

An adhesive pattern having an uneven shape may be formed on at least one of the bottom surface and the inner side surface of the step.

According to an embodiment, a semiconductor package includes a semiconductor substrate including a first substrate surface on which a first connection pad is exposed, a second substrate surface on which a second connection pad is exposed, and an RDL connecting the first connection pad to the second connection pad, an image sensor chip disposed at a center portion of the first substrate surface of the semiconductor substrate and connected to the first connection pad, a cover glass disposed spaced apart from an upper portion of the image sensor chip, having a greater area than the image sensor chip, having a center portion aligned to a center portion of the image sensor chip in a plan view, a molding structure including a step configured to accommodate an edge of the cover glass and disposed on the first substrate surface of the semiconductor substrate to surround the image sensor chip, an adhesive layer disposed at the step and configured to fix the cover glass to the molding structure, and a connection terminal connected to the second connection pad. In a plan view, an inner side surface of the step may be spaced outward and apart from a side surface of the cover glass such that the adhesive layer is disposed in a space between a bottom surface of the step and a lower surface of the cover glass and in a space between the inner side surface of the step and the side surface of the cover glass.

According to an embodiment, a semiconductor package manufacturing method includes forming a molding structure with an upper portion having a step on an edge of a first substrate surface of a semiconductor substrate, disposing an image sensor chip at a center portion of the first substrate surface, and bonding a lower surface and a side surface of a cover glass to a bottom surface and an inner side surface of the step formed on an upper end portion of the molding structure.

The bonding of the lower surface and the side surface of the cover glass to the bottom surface and the inner side surface of the step may include applying an adhesive material to the bottom surface and the inner side surface of the step and placing the cover glass on the adhesive material applied to the step.

The disposing of the molding structure may include installing a dam structure on an inner side and an outer side of a boundary of a unit semiconductor package forming region, forming the molding structure by injecting a molding material in an interspace of the dam structure installed on the inner side and the outer side, of the boundary of the unit semiconductor package forming region and removing the dam structure.

### BRIEF DESCRIPTION OF THE DRAWINGS

The foregoing and other aspects, features, and advantages of certain embodiments in the disclosure will become apparent from the following detailed description with reference to the accompanying drawings.

FIG. 1 is a plan view of a semiconductor package according to an embodiment.

FIG. 2 is a cross-sectional view taken along a line I-I′ of FIG. 1.

FIG. 3 is an enlarged view of a portion A of FIG. 2.

FIG. 4 is a cross-sectional perspective view illustrating a portion of an upper side of a molding structure according to an embodiment.

FIG. 5 is a cross-sectional view of a semiconductor package according to an embodiment.

FIG. 6 is a cross-sectional view of a semiconductor package according to an embodiment.

FIG. 7 is a plan view of a semiconductor package according to an embodiment.

FIG. 8 is a cross-sectional view of the semiconductor package according to an embodiment.

FIG. 9 is a plan view of semiconductor package according to an embodiment.

FIG. 10 is a cross-sectional view taken along a line K-K′ of FIG. 9.

FIG. 11 is a cross-sectional view taken along a line L-L′ of FIG. 9.

FIG. 12A, FIG. 12B, FIG. 12C, and FIG. 12D illustrate a semiconductor package manufacturing method, according to an embodiment.

FIG. 13A, FIG. 13B, FIG. 13C illustrate a cover glass according to some embodiments.

### DETAILED DESCRIPTION

Hereinafter, embodiments will be described in detail with reference to the accompanying drawings. Embodiments should be understood to include all changes, equivalents, and replacements within the inventive concept and the technical scope of the disclosure. Aspects of the inventive concept may be embodied in different forms and should not be construed as limited to embodiments set forth herein. Rather, embodiments are provided so that this disclosure will be thorough and complete, and will fully convey the scope of the disclosure to those skilled in the art.

The terminology used herein is for the purpose of describing particular embodiments only and is not intended to be limiting. The singular forms “a”, “an”, and “the” include the plural forms as well, unless the context clearly indicates otherwise. It will be further understood that the terms “comprises/comprising” and/or “includes/including” when used herein, specify the presence of stated features, integers, steps, operations, elements, components, or groups thereof, but do not preclude the presence or addition of one or more other features, integers, steps, operations, elements, components, or groups thereof.

Unless otherwise defined, all terms including technical and scientific terms used herein have the same meaning as commonly understood by one of ordinary skill in the art to which embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing aspects of the inventive concept with reference to the accompanying drawings, like reference numerals refer to like components and a repeated description related thereto may be omitted. In the description, detailed description of well-known related structures or functions may be omitted when such description may obscure aspects of the present disclosure.

In addition, terms such as first, second, A, B, (a), (b), and the like may be used to describe components. These terms are used only for the purpose of discriminating one component from another component, and the nature, the sequences, or the orders of the components are not limited by the terms. When one component is described as being “connected”, “coupled”, or “attached” to another component, it should be understood that one component may be connected or attached directly to another component, and an intervening component may also be “connected”, “coupled”, or “attached” to the components.

The same name may be used to describe an element throughout the description. Unless stated otherwise, the description of an embodiment may be applicable to other embodiments, and a repeated description related thereto may be omitted.

According to some embodiments, a cover glass may be mounted on a molding structure having a step disposed at an upper portion thereof. The step in the molding structure may receive the cover glass and reduce the likelihood of delamination of the cover glass, for example, due to lateral external forces by providing a physical support structure in addition to an adhesive force. For example, an inner side surface of the step may function as the physical support structure, which may resist the lateral external forces.

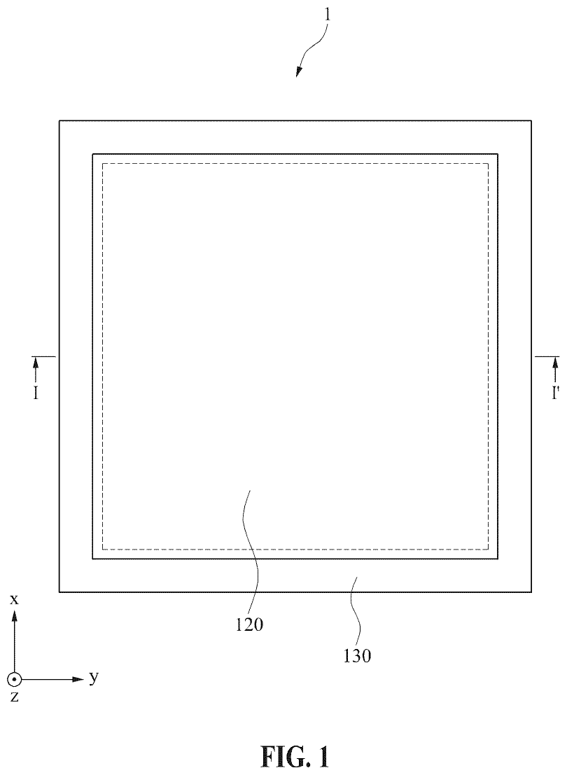

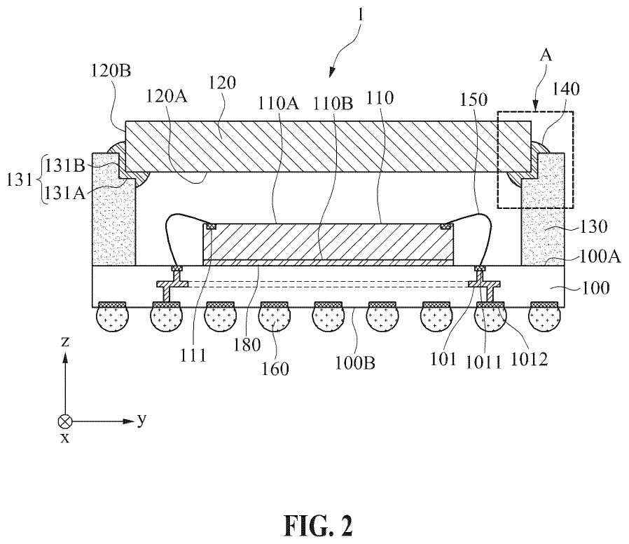

FIG. 1 is a plan view of a semiconductor package according to an embodiment. FIG. 2 is a cross-sectional view taken along a line I-I′ of FIG. 1.

Referring to FIG. 1 and FIG. 2, a semiconductor package 1 may be provide for an electronic device such as an image sensor. The semiconductor package 1 may include a semiconductor substrate 100, an image sensor chip 110, a conductive wire 150, cover glass 120, a molding structure 130, an adhesive layer 140, and a plurality of connection terminals 160. The image sensor chip 110 may be disposed on the semiconductor substrate 100. The conductive wire 150 may electrically connect the image sensor chip 110 to the semiconductor substrate 100. The cover glass 120 may be disposed to cover the upper portion of the image sensor chip 110. The molding structure 130 may surround the image sensor chip 110. The adhesive layer 140 may bond the molding structure 130 and the cover glass 120. The plurality of connection terminals 160 may be disposed on the lower portion of the semiconductor substrate 100. For example, the semiconductor package 1 may be a ball grid array (BGA) in which the connection terminals 160 are formed as solder balls.

The image sensor chip 110 is an example, and one or more additional chips, such as a memory chip or a logic chip may be stacked below the image sensor chip 110. In an example where the semiconductor package 1 includes a memory chip, the memory chip may be, for example, a volatile memory chip like dynamic random access memory (DRAM) or static random access memory (SRAM) or a non-volatile memory chip like phase-change random access memory (PRAM), magneto-resistive random access memory (MRAM), ferroelectric random access memory (FeRAM), or resistive random access memory (RRAM). In an example where the semiconductor package 1 includes a logic chip, the logic chip may be, for example, a microprocessor like a central processing unit (CPU), a graphics processing unit (GPU), or an application processor (AP), an analog device, or a digital signal processor.

The semiconductor substrate 100 (or a substrate) may support the image sensor chip 110. The semiconductor substrate 100 may include a first substrate surface 100A on which the image sensor chip 110 may be disposed and a second substrate surface 100B disposed opposite to the first substrate surface 100A. A redistribution layer (RDL) 101 may be formed on the semiconductor substrate 100. The RDL 101 may form an electrical path extending from the first substrate surface 100A to the second substrate surface 100B of the semiconductor substrate 100. For example, a plurality of first connection pads 1011, connected to the conductive wire 150, may be arranged on the first substrate surface 100A of the semiconductor substrate 100 and exposed to the outside, and a plurality of second connection pads 1012, connected to the connection terminals 160, may be arranged on the second substrate surface 100B of the semiconductor substrate 100 and exposed to the outside. The RDL 101 may electrically connect the first connection pads 1011 to the second connection pads 1012. For example, the RDL 101 may have a fan-out structure from the first connection pads 1011 to the second connection pads 1012.

The RDL 101 may include a plurality of redistribution line patterns, a plurality of redistribution vias, and a redistribution insulating layer. The redistribution insulating layer may be formed, for example, from a photo imageable dielectric (PID) or photosensitive polyimide (PSPI). The redistribution line patterns and the redistribution vias may be metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or alloys thereof, but are not limited thereto. For example, the redistribution line patterns and redistribution vias may be formed by stacking a metal or an alloy on a seed layer that includes titanium, a titanium nitride, or titanium tungsten.

The plurality of first connection pads 1011 may be arranged on the first substrate surface 100A of the semiconductor substrate 100. The plurality of first connection pads 1011 may be disposed outside the perimeter of the image sensor chip 110. Although two first connection pads 1011 are illustrated in the drawings, this is for ease of description through a cross-sectional view. It should be noted that the plurality of first connection pads 1011 may be connected to a plurality of chip pads 111 formed on the image sensor chip 110. The plurality of first connection pads 1011 may be connected to the plurality of chip pads 111 through the conductive wire 150.

The image sensor chip 110 may have a structure in which a plurality of unit pixels may be arranged in an array. Each of the plurality of unit pixels positioned in an image sensing region may detect light using a photodiode (PD) and may convert the detected light into an electrical signal to generate an image signal. For example, the plurality of unit pixels may include a complementary metal oxide semiconductor (CMOS) image sensor. However, this is only an example, and the plurality of unit pixels may also include a charge coupled device (CCD) image sensor, and embodiments are not limited thereto.

The image sensor chip 110 may be mounted on the first substrate surface 100A of the semiconductor substrate 100. The image sensor chip 110 may be disposed at a center portion of the first substrate surface 100A of the semiconductor substrate 100. The image sensor chip 110 may include a first surface 110A and a second surface 110B disposed opposite to the first surface 110A. The image sensor chip 110 may be disposed such that the second surface 110B faces the first substrate surface 100A of the semiconductor substrate 100. The plurality of chip pads 111 positioned at the edges may be arranged on the first surface 110A of the image sensor chip 110. The chip pads 111 may be electrically connected to the RDL 101 of the semiconductor substrate 100 through the conductive wire 150. The chip pads 111 may include a conductive layer such as a metal, a metal nitride, or conductive carbon, or a combination thereof. For example, the chip pads 111 may include materials such as copper (Cu), cobalt (Co), aluminum (Al), tin (Sn), nickel (Ni), gold (Au), silver (Ag), tungsten (W), a tungsten nitride (WN), titanium (Ti), a titanium nitride (TiN), tantalum (Ta), a tantalum nitride (TaN), ruthenium (Ru), or platinum (Pt), or a combination thereof. The chip pads 111 may be electrically connected to semiconductor devices of the image sensor chip 110. For example, the image sensor chip 110 may include devices formed in or on the image sensor chip 110.

A bonding member 180 may be disposed between the semiconductor substrate 100 and the image sensor chip 110. The bonding member 180 may be formed between the first substrate surface 100A of the semiconductor substrate 100 and the second surface 110B of the image sensor chip 110. The bonding member 180 may bond the image sensor chip 110 to the semiconductor substrate 100. The bonding member 180 may be formed by a bonding material applied to the first substrate surface 100A of the semiconductor substrate 100 in the process of manufacturing the semiconductor package 1.

The conductive wire 150 may connect the image sensor chip 110 to the first substrate surface 100A of the semiconductor substrate 100. The conductive wire 150 may electrically connect the image sensor chip 110 to the RDL 101 of the semiconductor substrate 100. End portions of the conductive wire 150 may be connected to the chip pads 111 of the image sensor chip 110 and the first connection pads 1011 of the semiconductor substrate 100, respectively. The semiconductor package 1 may include a plurality of conductive wires 150, and each conductive wire 150 may individually connect the chip pads 111 formed on the image sensor chip 110 to the plurality of first connection pads 1011 formed on the semiconductor substrate 100. For example, the conductive wires 150 may be connected to the chip pads 111 and the first connection pads 1011 through soldering. Through the conductive wires 150, the image sensor chip 110 may be electrically connected to circuits of the semiconductor substrate 100.

The semiconductor package 1 may include a molding compound disposed to surround the bonding member 180 and sidewalls of the image sensor chip 110. For example, the molding compound may at least partially cover the conductive wires 150. The molding compound may stabilize the conductive wires 150 and secure the image sensor chip 110. The molding compound may have a height in the Z-direction that exposes the first surface 110A of the image sensor chip 110.

The cover glass 120 may be disposed above the image sensor chip 110. The cover glass 120 may cover the first surface 110A of the image sensor chip 110 while being spaced apart from the first surface 110A of the image sensor chip 110. The cover glass 120 may be formed of a light-transmissive material. For example, the cover glass 120 may be formed of glass, a polymer, such as ethylene tetrafluoroethylene (ETFE), or glass fiber-reinforced polymer.

Light may be incident on the first surface 110A of the image sensor chip 110 through the cover glass 120. For example, the cover glass 120 may serve as an optical path that allows light to be input to the image sensor chip 110 while protecting the image sensor chip 110. The cover glass 120 may be formed to have a width larger than the X-axis and/or Y-axis width of the image sensor chip 110. In a plan view, the cover glass 120 may have a larger area than the image sensor chip 110. A center portion of the cover glass 120 may align with a center portion of the image sensor chip 110 in a plan view.

The molding structure 130 may be disposed on the first substrate surface 100A of the semiconductor substrate 100. The molding structure 130 may surround and protect the image sensor chip 110. The molding structure 130 may be formed, for example, from an epoxy mold compound (EMC). The EMC may include, for example, a resin-based resin, a filler, and a curing agent. The molding structure 130 may be formed between the upper portion of the semiconductor substrate 100 and the cover glass 120. The molding structure 130 may surround the perimeter of the image sensor chip 110. The molding structure 130 may include a step 131. The step 131 may be configured to accommodate the edge of the cover glass 120. The step 131 may accommodate an edge portion of a lower surface 120A of the cover glass 120 and a lower edge portion of a side surface 120B of the cover glass 120. The molding structure 130 may be disposed on a peripheral portion of the first substrate surface 100A of the semiconductor substrate 100. For example, molding structure 130 may cover edge portion of the first substrate surface 100A of the semiconductor substrate 100. An outer surface of the molding structure 130 may be positioned on a same plane as the outer surface of the semiconductor substrate 100.

An adhesive material for forming the adhesive layer 140 may be disposed between the step 131 of the molding structure 130 and the cover glass 120. The adhesive layer 140 may be applied to the surface of the step 131 of the molding structure 130 to fix the cover glass 120 to the molding structure 130. The adhesive layer 140 may fix the lower surface 120A and the side surface 120B of the cover glass 120 to the molding structure 130. The adhesive material for forming the adhesive layer 140 may be applied to a bottom surface 131A and an inner side surface 131B of the step 131.

The connection terminals 160 may be disposed on the second substrate surface 100B of the semiconductor substrate 100. The connection terminals 160 may be connected to the second substrate surface 100B of the semiconductor substrate 100. For example, the connection terminals 160 may be soldered to the second connection pads 1012 exposed on the second substrate surface 100B of the semiconductor substrate 100, thereby being electrically connected to the RDL 101. The semiconductor package 1 may be electrically connected to an exterior package, device, or connection. For example, the semiconductor package 1 may be electrically connected to another semiconductor package 1 or a motherboard through the connection terminals 160.

The connection terminals 160 may be arranged in an array on the second substrate surface 100B of the semiconductor substrate 100. As shown in FIG. 2, the connection terminals 160 may be arranged on the semiconductor substrate 100 in a fan-out structure. The connection terminals 160 may be omitted from the second substrate surface 100B of the semiconductor substrate 100 corresponding to the lower portion in the Z-direction of the image sensor chip 110, but embodiments are not limited thereto. For example, the connection terminals 160 may be solder balls, but embodiments are not limited thereto.

While the image sensor chip 110 is illustrated as being flip chip mounted on the semiconductor substrate 100, with the plurality of chip pads 111 disposed on an upper surface of the image sensor chip 110, which is the first surface 110A, the image sensor chip 110 may be configured with the plurality of chip pads 111 disposed on a lower surface of the image sensor chip 110, which is the second surface 110B. For example, the bonding member 180 may be omitted, and the image sensor chip 110 may be bounded to the semiconductor substrate 100 by solder connecting the plurality of chip pads 111 to the first connection pads 1011 of the semiconductor substrate 100.

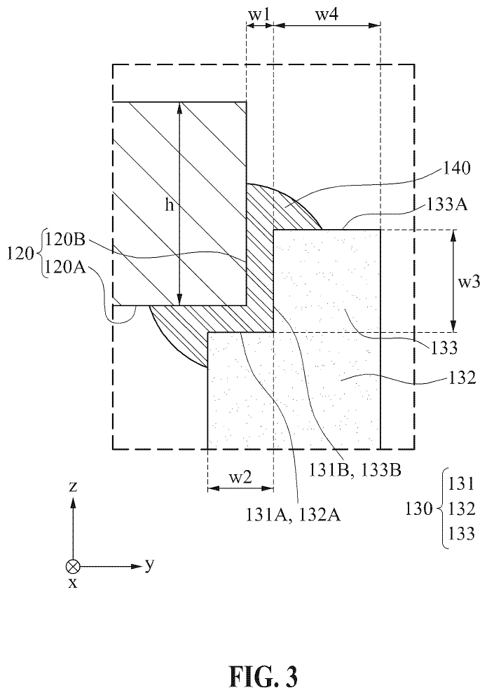

Referring to FIG. 2 and FIG. 3, in a state in which the first substrate surface 100A is viewed, the inner side surface 131B of the step 131 may be spaced outwardly by a width w1 from the side surface 120B of the cover glass 120. In other words, in a state in which the first substrate surface 100A is viewed, the width of the cover glass 120 may be less than the width between the inner side surfaces 131B of the steps 131 facing each other. In this case, the adhesive layer 140 may be formed in a space between the bottom surface 131A of the step 131 and the lower surface 120A of the cover glass 120, and also in a space between the inner side surface 131B of the step 131 and the side surface 120B of the cover glass 120. For example, the width w1 may be about 0.5 millimeters (mm) to about 2 mm, but embodiments are not limited thereto. Similarly, the space between the bottom surface 131A of the step 131 and the lower surface 120A of the cover glass 120 may be about 0.5 millimeters (mm) to about 2 mm high in the Z-direction.

As the adhesive layer 140 secures the side surface 120B of the cover glass 120, it may be possible to ensure a sufficient adhesive area, reducing the likelihood of the cover glass 120 delaminating from the molding structure 130. For example, the height h of the cover glass 120 may be greater than the height w3 of a protrusion 133. According to this structure, the adhesive layer 140 may adhere to the side surface 120B of the cover glass 120 that protrudes beyond the inner side surface 131B of the step 131 and the possibility of the cover glass 120 delaminating from the molding structure 130 may be further reduced compared to when the adhesive layer 140 is formed only between the lower surface 120A of the cover glass 120 and the molding structure 130.

A sum of the area of the bottom surface 131A of the step 131 and the area of the inner side surface 131B of the step 131 may be greater than the cross-sectional area of the molding structure 130 in a state in which the first substrate surface 100A is viewed. Here, the aforementioned cross-sectional area may be understood as the sum of the area of the bottom surface 131A and the area of the uppermost surface 133A of the molding structure 130. The area of the inner side surface 131B of the step 131 may be larger than the area of the uppermost surface 133A of the molding structure 130. According to this example structure, compared to the case of bonding the cover glass 120 to a flat end portion without the step 131, it may be possible to reduce the likelihood of delamination of the cover glass 120, e.g., due to lateral external forces, by providing a physical support structure in addition to an adhesive force. For example, the inner side surface 131B of the step 131 may function as the physical support structure, which may resist lateral external forces. Furthermore, since the molding structure 130 and the cover glass 120 may be adhered over a larger area than the area where the flat end portion without the step 131 and the cover glass 120 may be adhered, the possibility of delamination of the cover glass 120 may be reduced.

In a state in which the cover glass 120 is fixed to the molding structure 130, the cover glass 120 may have a shape protruding above the uppermost surface 133A of the molding structure 130. According to this example shape, the adhesive layer 140 may adhere to the side surface of a protruding portion of the cover glass 120, thereby increasing the adhesive area to be greater than an area disposed between the molding structure 130 and the cover glass 120.

The molding structure 130 may include a wall 132 disposed on the first substrate surface 100A and a protrusion 133 protruding upward from the outer edge of the wall 132. For example, the outer surface of the protrusion 133 and the outer surface of the wall 132 may be positioned on the same plane. The step 131 of the molding structure 130 may be understood as including an upper surface 132A of the wall 132 and an inner side surface 133B of the protrusion 133. For example, the height w3 of the protrusion 133 may be greater than the width w4 of the uppermost surface 133A of the protrusion 133. For example, the height h of the cover glass 120 may be greater than the height w3 of the protrusion 133. For example, the height h of the cover glass 120 may be greater than the width w4 of the uppermost surface 133A of the protrusion 133. According to this structure, the molding structure 130 and the cover glass 120 may be adhered with a larger area compared to a flat end portion without the step 131 and the cover glass 120, reducing the possibility of delamination of the cover glass 120.

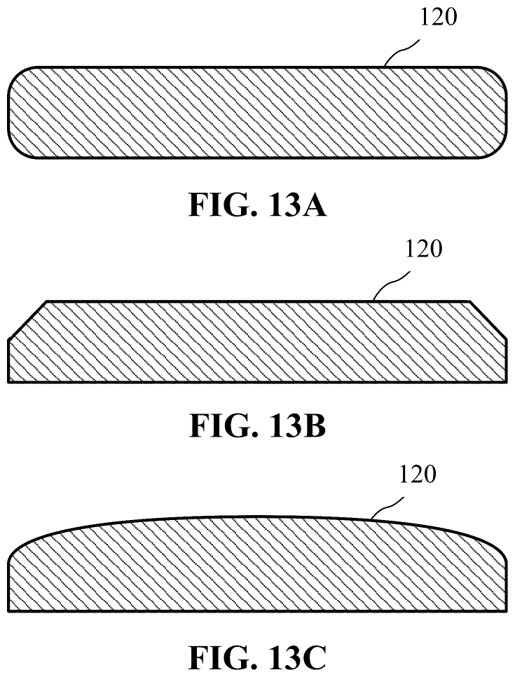

While the cover glass 120 is illustrated having a flat sidewall and a square upper edge shape, embodiments are not limited thereto. For example, the sidewall of the cover glass 120 may have a rounded shape (see FIG. 13A) or a C shape. In another example, the upper surface of the cover glass 120 may have a convex shape (see FIG. 13C). In still another example, the edge shape may be a bevel shape (see FIG. 13B) or a rounded shape (similar to FIG. 13A). The edge shape may reduce a likelihood of damage due to an impact and may improve light collection. Further, the sidewall of the cover glass 120 may be polished to improve adhesion of the adhesive layer 140. For example, the sidewall of the cover glass 120 may have a ground finish or a polished finish.

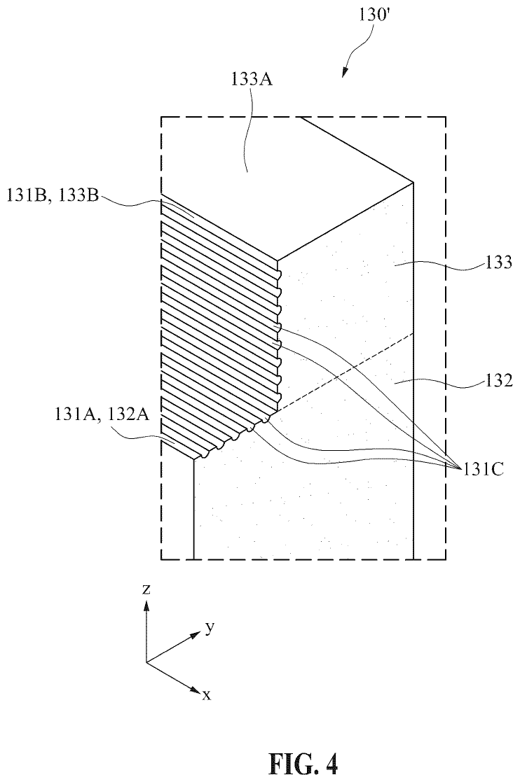

FIG. 4 is a cross-sectional perspective view illustrating a portion of an upper side of a molding structure according to an embodiment.

Referring to FIG. 4, a molding structure 130′ may include the wall 132 disposed on the first substrate surface 100A and the protrusion 133 protruding upward from the outer edge portion of the wall 132. The upper surface 132A of the wall 132 and the inner side surface 133B of the protrusion 133 may be understood as the bottom surface 131A and the inner side surface 131B of the step 131 formed in the molding structure 130′, respectively.

An adhesive pattern 131C may be formed on at least one of the bottom surface 131A and the inner side surface 131B of the step 131. The adhesive pattern 131C may be a uneven surface formed on at least one of the bottom surface 131A and the inner side surface 131B of the step 131. According to the adhesive pattern 131C, an adhesive material used to form the adhesive layer 140 (see FIG. 3) may remain stably on the step 131. For example, the adhesive pattern 131C may reduce the likelihood of a void forming between the cover glass 120 and the molding structure 130′, where the adhesive layer 140 is not formed, thereby lowering the possibility of delamination of the cover glass 120.

The adhesive pattern 131C may include, for example, a linear groove parallel to the edge of the molding structure 130′, but embodiments are not limited thereto. For example, the groove may be formed perpendicular or inclined to the edge of the molding structure 130′, and the shape of the groove may vary, including an X-shape, a zigzag, or a wave pattern. The adhesive pattern 131C may be formed, for example, through a laser processing technique after the overall structure of the molding structure 130′ is formed.

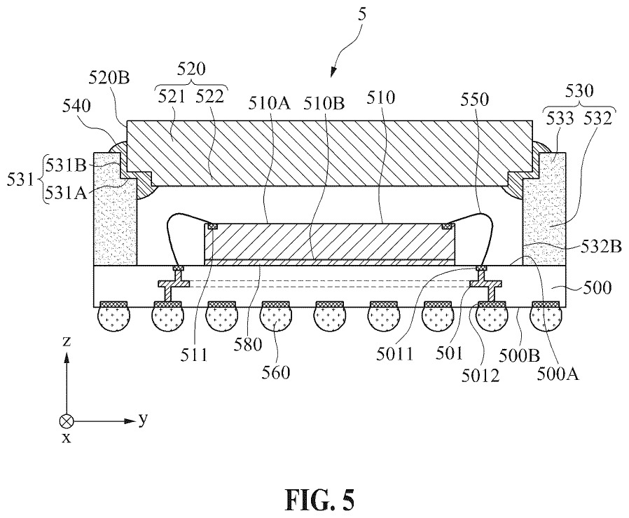

Hereinafter, a semiconductor package according to various examples is described with reference to FIGS. 5 to 11. In describing an exemplary semiconductor package with reference to FIGS. 5 to 11, terms mentioned should be understood as having the same or similar configurations, unless otherwise stated. Even if not explicitly mentioned in the specific examples, it should be noted that the structure of a heat dissipation member applied to embodiments described herein may be applied in the same or similar manner.

FIG. 5 is a cross-sectional view of a semiconductor package according to an embodiment.

Referring to FIG. 5, a semiconductor package 5 may include a semiconductor substrate 500 including an RDL 501, an image sensor chip 510 disposed on a first substrate surface 500A of the semiconductor substrate 500, a conductive wire 550 electrically connecting the image sensor chip 510 to the RDL 501 of the semiconductor substrate 500, a cover glass 520 disposed to cover the upper portion of the image sensor chip 510, a molding structure 530 forming a gap between the image sensor chip 510 and the cover glass 520 and surrounding the image sensor chip 510, and a plurality of connection terminals 560 disposed on a second substrate surface 500B of the semiconductor substrate 500.

The semiconductor substrate 500 may include the first substrate surface 500A and the second substrate surface 500B disposed opposite to the first substrate surface 500A. A first connection pad 5011, to which the conductive wire 550 is connected, may be exposed on the first substrate surface 500A, while a second connection pad 5012 may be exposed on the second substrate surface 500B. A plurality of connection terminals 560, which may be electrically connected to the RDL 501 through the second connection pad 5012, may be disposed on the second substrate surface 500B.

The image sensor chip 510 may include a first surface 510A and a second surface 510B disposed opposite to the first surface 510A. The image sensor chip 510 may be disposed such that the second surface 510B faces the first substrate surface 500A of the semiconductor substrate 500. A bonding member 580 may be disposed between the semiconductor substrate 500 and the image sensor chip 510. A chip pad 511 to which the conductive wire 550 is connected may be disposed on the first surface 510A of the image sensor chip 510.

The cover glass 520 may include a main glass portion 521 supported by a step 531 and a lower glass portion 522 protruding downward from the main glass portion 521 toward the first substrate surface 100A. The lower glass portion 522 may have a smaller area than the main glass portion 521 in a plan view. The lower glass portion 522 may be fixed to an inner side surface 532B of the molding structure 530 by an adhesive layer 540. The interlocking structure of the cover glass 520 and the molding structure 530 may enhance the bonding strength between the cover glass 520 and the molding structure 530, thereby reducing the possibility of delamination of the cover glass 520.

The molding structure 530 may be provided with the step 531 capable of accommodating the edge of the main glass portion 521. The step 531 may accommodate the edge of the lower surface of the main glass portion 521 and the lower edge of the side surface of the main glass portion 521. The inner side surface of the molding structure 530 adjacent to the step 531 may face the side surface of the lower glass portion 522.

An adhesive material for forming the adhesive layer 540 may be applied to the step 531 and may fix the cover glass 520 to the molding structure 530. As shown, the adhesive layer 540 may fix the lower surface and a side surface of the main glass portion 521 and a side surface of the lower glass portion 522 to the molding structure 530. The adhesive material for forming the adhesive layer 540 may be applied to the bottom surface 531A and inner side surface 531B of the step 531. In the process of bonding the cover glass 520 to the molding structure 530, some of the adhesive material applied to the step 531 may spread along the inner side surface of the molding structure 530, resulting in the side surface of the lower glass portion 522 being adhered to the inner surface of the molding structure 530 by the adhesive material. This structure may increase the adhesive area between the cover glass 520 and the molding structure 530, thereby reducing the possibility of the cover glass 520 delaminating from the molding structure 530.

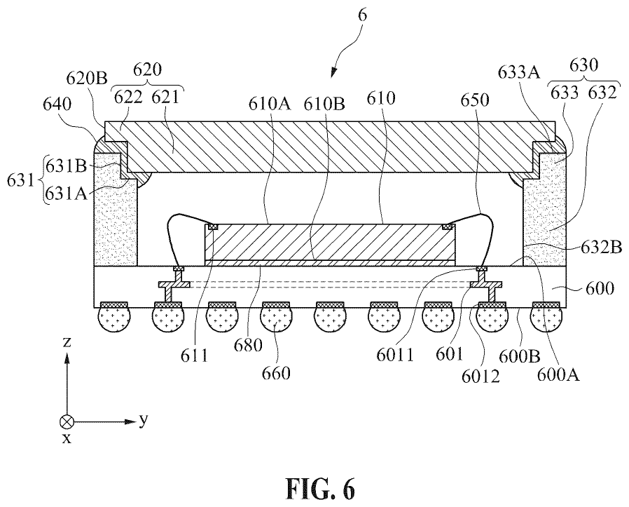

FIG. 6 is a cross-sectional view of a semiconductor package according to an embodiment.

Referring to FIG. 6, a semiconductor package 6 may include a semiconductor substrate 600 including an RDL 601, an image sensor chip 610 disposed on a first substrate surface 600A of the semiconductor substrate 600, a conductive wire 650 electrically connecting the image sensor chip 610 to the RDL 601 of the semiconductor substrate 600, a cover glass 620 disposed to cover the upper portion of the image sensor chip 610, a molding structure 630 forming a gap between the image sensor chip 610 and the cover glass 620 and surrounding the image sensor chip 610, and a plurality of connection terminals 660 disposed on a second substrate surface 600B of the semiconductor substrate 600.

The semiconductor substrate 600 may include the first substrate surface 600A and a second substrate surface 600B disposed opposite to the first substrate surface 600A. A first connection pad 6011 may be exposed on the first substrate surface 600A and may be connected to the conductive wire 650, while a second connection pad 6012 may be exposed on the second substrate surface 600B. The plurality of connection terminals 660 may be disposed on the second substrate surface 600b and may be electrically connected to the RDL 601 through the second connection pad 6012.

The image sensor chip 610 may include a first surface 610A and a second surface 610B disposed opposite to the first surface 610A. The image sensor chip 610 may be disposed such that the second surface 610B faces the first substrate surface 600A of the semiconductor substrate 600. A bonding member 680 may be disposed between the semiconductor substrate 600 and the image sensor chip 610. A chip pad 611 to which the conductive wire 650 is connected may be disposed on the first surface 601A of the image sensor chip 610.

The cover glass 620 may include a main glass portion 621 supported by a step 631 and a side glass portion 622 protruding upwardly and outwardly from the upper side of the main glass portion 621. For example, in a plan view, an area of the main glass portion 621 may be less than an area of the side glass portion 622. The side glass portion 622 may be fixed to an uppermost surface 633A of the molding structure 630 by an adhesive layer 640. The interlocking structure of the cover glass 620 and the molding structure 630 may enhance the bonding strength between the cover glass 620 and the molding structure 630, thereby reducing the possibility of delamination of the cover glass 620.

The molding structure 630 may be provided with the step 631 capable of accommodating the edge of the main glass portion 621. The step 631 may accommodate the edge of the lower surface of the main glass portion 621 and the lower edge of the side surface of the main glass portion 621. An uppermost surface 633A of the molding structure 630 may face the lower surface of the side glass portion 622.

An adhesive material for forming the adhesive layer 640 may be applied to the step 631 to fix the cover glass 620 to the molding structure 630. As illustrated, the adhesive layer 640 may fix the lower surface and the side surface of the main glass portion 621 and the lower surface of the side glass portion 622 to the molding structure 630. The adhesive material for forming the adhesive layer 640 may be applied to a bottom surface 631A and an inner side surface 631B of the step 631. In the process of bonding the cover glass 620 to the molding structure 630, some of the adhesive material applied to the step 631 may spread outward along the uppermost surface 633A of the molding structure 630, resulting in the lower surface of the side glass portion 622 being bonded to the uppermost surface 633 A of the molding structure 630 by the adhesive material. This structure may increase the adhesive area between the cover glass 620 and the molding structure 630, reducing the likelihood of the cover glass 620 delaminating from the molding structure 630. It should be noted that, for example, the adhesive material for forming the adhesive layer 640 may also be applied to the uppermost surface 633A of the molding structure 630.

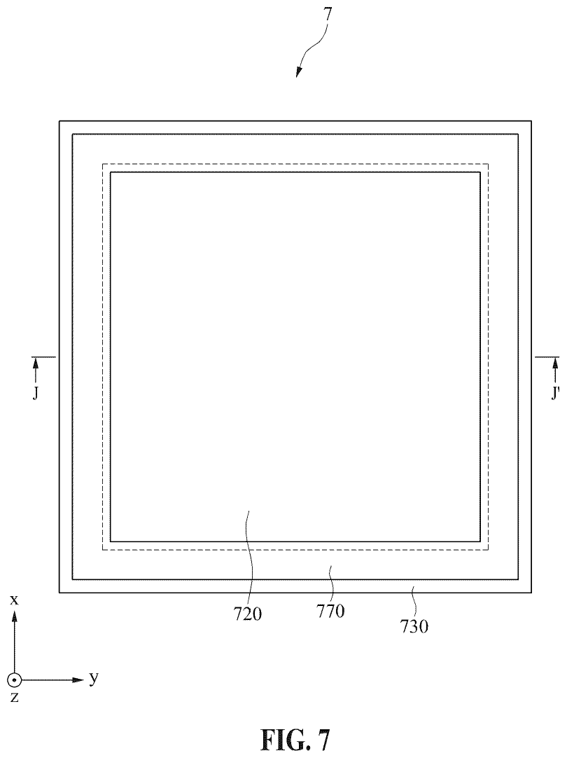

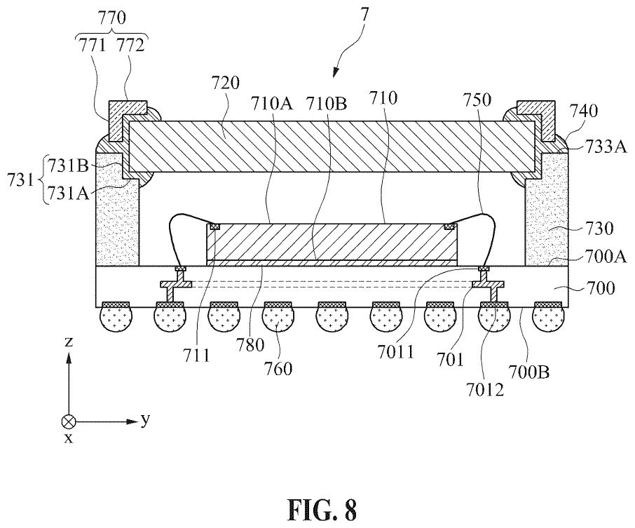

FIG. 7 is a plan view of a semiconductor package according to an embodiment. FIG. 8 is a cross-sectional view of the semiconductor package according to an embodiment.

Referring to FIGS. 7 and 8, a semiconductor package 7 may include a semiconductor substrate 700 including an RDL 701, an image sensor chip 710 disposed on the first substrate surface 700A of the semiconductor substrate 700, a conductive wire 750 electrically connecting the image sensor chip 710 to the RDL 701 of the semiconductor substrate 700, a cover glass 720 disposed to cover the upper portion of the image sensor chip 710, a molding structure 730 forming a gap between the image sensor chip 710 and the cover glass 720 and surrounding the image sensor chip 710, a plurality of connection terminals 760 disposed on a second substrate surface 700B of the semiconductor substrate 700, and a reinforcing body 770 disposed on the upper side of the cover glass 720.

The semiconductor substrate 700 may include the first substrate surface 700A and the second substrate surface 700B disposed opposite to the first substrate surface 700A. A first connection pad 7011 to which the conductive wire 750 is connected may be exposed on the first substrate surface 700A, while a second connection pad 7012 may be exposed on the second substrate surface 700B. A plurality of connection terminals 760, which may be electrically connected to the RDL 701 through the second connection pad 7012, may be disposed on the second substrate surface 700B.

The image sensor chip 710 may include a first surface 710A and a second surface 710B disposed opposite to the first surface 710A. The image sensor chip 710 may be disposed such that the second surface 710B faces the first substrate surface 700A of the semiconductor substrate 700. A bonding member 780 may be disposed between the semiconductor substrate 700 and the image sensor chip 710. A chip pad 711 to which the conductive wire 750 is connected may be disposed on the first surface 710A of the image sensor chip 710.

The cover glass 720 may be fixed to the molding structure 730 by an adhesive layer 740. The molding structure 730 may be provided with a step 731 capable of accommodating the edge of the cover glass 720. The step 731 may accommodate the edge of the lower surface of the cover glass 720 and the lower edge of the side surface of the cover glass 720.

An adhesive material for forming the adhesive layer 740 may be applied to the step 731 to fix the cover glass 720 to the molding structure 730. As illustrated, the adhesive layer 740 may fix the lower surface and a side surface of the cover glass 720 to the molding structure 730. The adhesive material for forming the adhesive layer 740 may be applied to a bottom surface 731A and an inner side surface 731B of the step 731. This structure may increase the adhesive area between the cover glass 720 and the molding structure 730, reducing the likelihood of the cover glass 720 delaminating from the molding structure 730. The adhesive material may fix the cover glass 720 and the reinforcing body 770 to the cover glass 720 and the molding structure 730. For example, it is noted that the adhesive material may also be applied to an uppermost surface 733A of the molding structure 730 and the upper edge of the cover glass 720.

The reinforcing body 770 may be disposed in a position overlapping the molding structure 730 and the cover glass 720 in a state in which the first substrate surface 700A is viewed. The reinforcing body 770 may include, for example, a vertical portion 771 fixed to the side surface of the cover glass 720 and the uppermost surface 733A of the molding structure 730 by the adhesive layer 740, and a horizontal portion 772 fixed to the edge of the upper surface of the cover glass 720 by the adhesive layer 740. The reinforcing body 770 may reduce the likelihood of the cover glass 720 delaminating from the molding structure 730.

The reinforcing body 770 may be transparent or opaque. The reinforcing body 770 may be formed of a polymer. The reinforcing body 770 may have a size that is larger than the cover glass 720. For example, the reinforcing body 770 may have a size that maintains a gap between the reinforcing body 770 and the cover glass 720 that is between about 0.5 mm and about 2 mm. This gap may be formed at the sidewall of the cover glass 720 and at an upper surface of the cover glass 720.

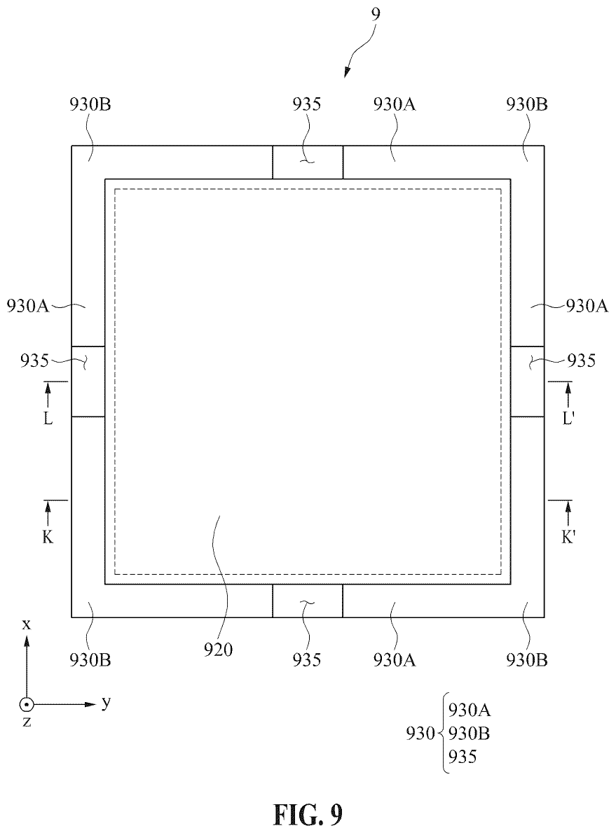

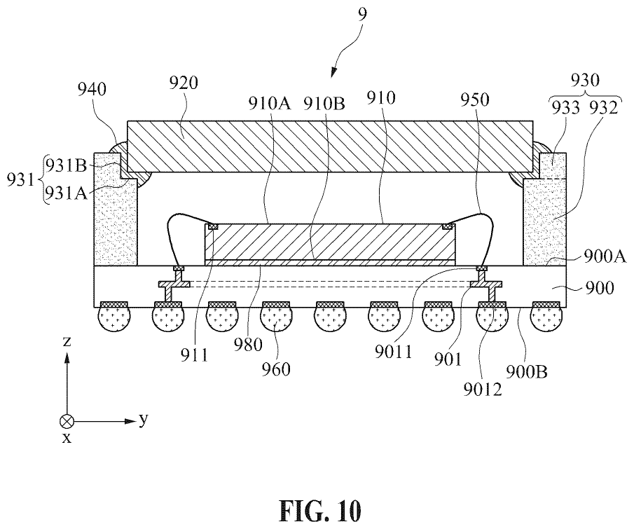

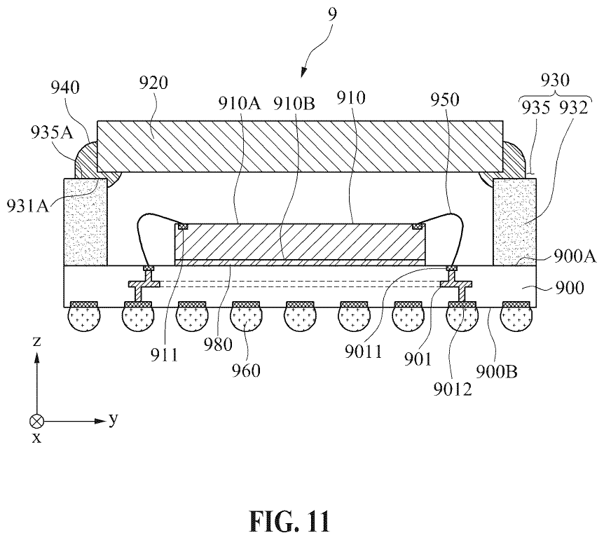

FIG. 9 is a plan view of semiconductor package according to an embodiment. FIG. 10 is a cross-sectional view taken along a line K-K′ of FIG. 9. FIG. 11 is a cross-sectional view taken along a line L-L′ of FIG. 9.

Referring to FIGS. 9 to 11, a semiconductor package 9 may include a semiconductor substrate 900 including an RDL 901, an image sensor chip 910 disposed on a first substrate surface 900A of the semiconductor substrate 900, a conductive wire 950 electrically connecting the image sensor chip 910 to the RDL 901 of the semiconductor substrate 900, a cover glass 920 disposed to cover the upper portion of the image sensor chip 910, a molding structure 930 forming a gap between the image sensor chip 910 and the cover glass 920 and surrounding the image sensor chip 910, and a plurality of connection terminals 960 disposed on a second substrate surface 900B of the semiconductor substrate 900.

The semiconductor substrate 900 may include the first substrate surface 900A and the second substrate surface 900B disposed opposite to the first substrate surface 900A. A first connection pad 9011 to which the conductive wire 950 is connected may be exposed on the first substrate surface 900A, while a second connection pad 9012 may be exposed on the second substrate surface 900B. The plurality of connection terminals 960 electrically connected to the RDL 901 through the second connection pad 9012 may be disposed on the second substrate surface 900B.

The image sensor chip 910 may include a first surface 910A and a second surface 910B opposite to the first surface 910A. The image sensor chip 910 may be disposed such that the second surface 910B faces the first substrate surface 900A of the semiconductor substrate 900. A bonding member 980 may be disposed between the semiconductor substrate 900 and the image sensor chip 910. A chip pad 911, to which the conductive wire 950 is connected, may be disposed on the first surface 910A of the image sensor chip 910.

The cover glass 920 may be fixed to the molding structure 930 by an adhesive layer 940. The molding structure 930 may be provided with a step 931 capable of accommodating the edge of the cover glass 920. The step 931 may accommodate the edge of the lower surface of the cover glass 920 and the lower edge of the side surface of the cover glass 920.

The molding structure 930 may include a wall 932 disposed on the first substrate surface 900A and a protrusion 933 protruding upward from the outer edge of the wall 932. The molding structure 930 may further include a storage space 935 in which an extra adhesive material of an adhesive material forming the adhesive layer 940 may remain, wherein the extra adhesive material may not be positioned between the step 931 and the cover glass 920.

The storage space 935 may be formed in a shape recessed in at least a portion of the protrusion 933. According to the storage space 935, when the adhesive material for forming the adhesive layer 940 is applied to the step 931, the extra adhesive material that remains in the storage space 935 may be supplied to a corresponding region even when some of the adhesive material seeps out. Therefore, the extra adhesive material may help ensure that the adhesive layer 940 between the cover glass 920 and the molding structure 930 is formed without any gaps.

Referring to FIGS. 9 and 10, the molding structure 930 may include a plurality of straight regions 930A and a plurality of corner regions 930B in a state in which the first substrate surface 900A is viewed. It may be understood that the corner regions 930B may refer to a portion in which a pair of adjacent straight regions 930A intersect with each other. For example, the storage space 935 may be formed in at least one straight region 930A of the plurality of straight regions 930A. Since a portion of the step 931 adjacent to the corner regions 930B may be blocked by two inner side surfaces 931B, an adhesive material may remain relatively stable in the portion adjacent to the corner regions 930B compared to a portion adjacent to the straight regions 930A. By forming the storage space 935 in the straight regions 930A, even when some adhesive material applied to the portion adjacent to the straight regions 930A leaks out, the extra adhesive material applied to the storage space 935 may compensate for the leakage. For example, the storage space 935 may be formed at the center portion of at least one straight region 930A. For example, the storage space 935 may not be formed in the corner regions 930B.

For example, a bottom surface 935A of the storage space 935 may be disposed on the same plane as the bottom surface 931A of the step 931. According to this structure, when the wall 932 is formed, the storage space 935 and the step 931 may be formed simultaneously by partially forming the protrusion 933 on the wall 932, reducing the time and cost associated with an overall manufacturing process.

The adhesive material for forming the adhesive layer 940 may be applied to the step 931 and may fix the cover glass 920 to the molding structure 930. As illustrated, the adhesive layer 940 may fix the lower surface and a side surface of the cover glass 920 to the molding structure 930. The adhesive material for forming the adhesive layer 940 may be applied to the bottom surface 931A and the inner side surface 931B of the step 931. This structure may increase the adhesive area between the cover glass 920 and the molding structure 930, and may reduce the likelihood of the cover glass 920 delaminating from the molding structure 930.

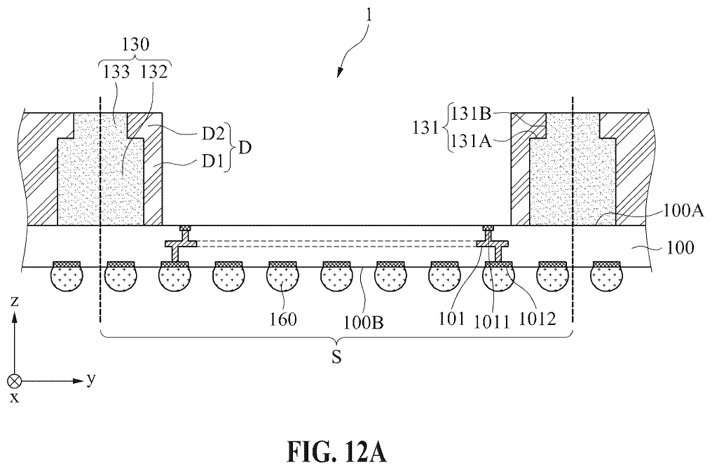

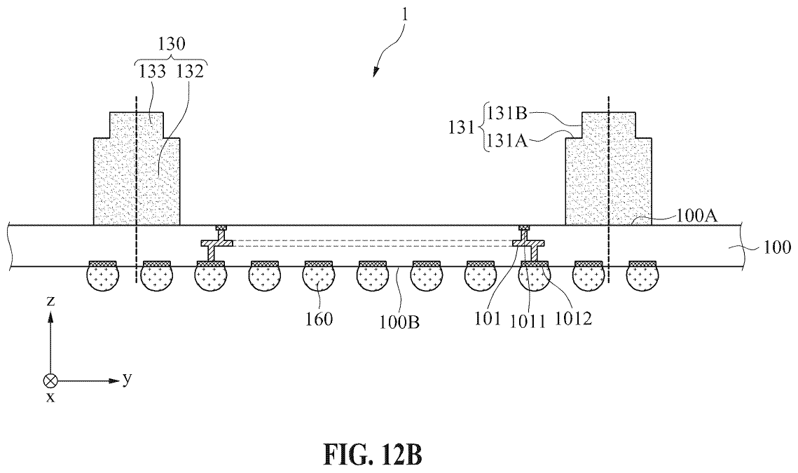

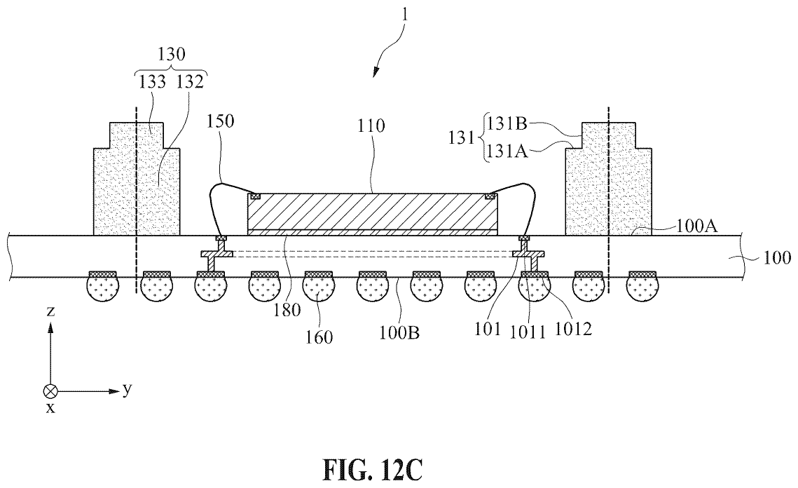

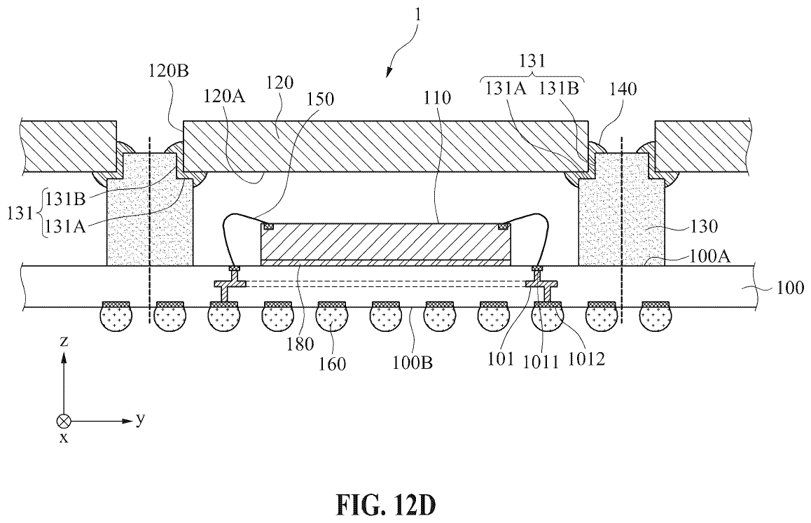

FIGS. 12A to 12D illustrate a semiconductor package manufacturing method, according to an embodiment.

Referring to FIG. 12A, the molding structure 130 with the step 131 formed on an upper end portion may be disposed at the edge portion of the first substrate surface 100A of the semiconductor substrate 100.

For example, to form the molding structure 130, a dam structure D corresponding to the shape of the molding structure 130 may be formed in advance on the first substrate surface 100A. For example, the dam structure D may be installed on an inside and an outside of the boundary of a unit semiconductor package formation region S on the first substrate surface 100A. A molding material may be injected into an interspace of the dam structures D installed inside and outside to form the molding structure 130. The molding material may be, for example, an epoxy mold compound (EMC). The EMC may include, for example, a resin-based resin, a filler, and a curing agent.

The dam structure D may include a base dam DI for forming the wall 132 of the molding structure 130 and a step dam D2 for forming the protrusion 133 of the molding structure 130. For example, the dam structure D, including the base dam DI and the step dam D2, may be separately fabricated and adhered to the first substrate surface 100A. In another example, with the base dam D1 disposed on the first substrate surface 100A, the wall 132 of the molding structure 130 may be formed by injecting the molding material. When the wall 132 is formed, with the step dam D2 disposed on the wall 132 and the base dam D1, the protrusion 133 of the molding structure 130 may be formed by injecting the molding material. When the molding structure 130 including the step 131 is formed, the dam structure D may be removed, as shown in FIG. 12B.

As opposed to the description provided above, the molding structure 130 may be formed separately and adhered to the first substrate surface 100A without forming the dam structure D. In another example, in a state in which a hollow pillar structure without a step is disposed on the first substrate surface 100A, the molding structure 130 with the step 131 formed on the upper end portion may be disposed on the edge portion of the first substrate surface 100A of the semiconductor substrate 100 by removing an inner portion of the end of a structure pillar. For example, a method of forming the step 131 may include physically removing a material, masking the outer edge of the end portion of the pillar structure or etching the unmasked inner part.

Referring to FIG. 12C, the image sensor chip 110 may be disposed at the center portion of the first substrate surface 100A. For example, the image sensor chip 110 may be fixed to the first substrate surface 100A through the bonding member 180 formed of an adhesive material, which may be disposed between the first substrate surface 100A and the image sensor chip 110. In a state in which the image sensor chip 110 is disposed on the first substrate surface 100A, the image sensor chip 110 and the semiconductor substrate 100 (e.g., the RDL 101) may be connected via the conductive wire 150. When the molding structure 130 is formed, by disposing the image sensor chip 110, it may be possible to inhibit or prevent the image sensor chip 110 from being damaged by the heat generated during the formation of the molding structure (130). In addition, the molding structure 130 may also be formed in a state in which the image sensor chip 110 is disposed first.

Referring to FIG. 12D, the bottom surface 131A and the inner side surface 131B of the step 131 formed at the upper end portion of the molding structure 130 may be adhered to the lower surface 120A and the side surface 120B of the cover glass 120. For example, the adhesive material for forming the adhesive layer 140 may be first applied to the bottom surface 131A and the inner side surface 131B of the step 131, and then the cover glass 120 may be placed on the adhesive material applied to the step 131. Alternatively, it should be noted that the adhesive material may also be applied after the cover glass 120 is placed on the step 131. When the adhesive material is applied first, it may be advantageous for forming a uniform adhesive layer 140 without a void not only on the inner side surface 131B of the step 131 but also on the bottom surface 131A of the step 131, thereby reducing the likelihood of delamination of the cover glass 120.

Furthermore, as shown in FIGS. 12A to 12D, a plurality of semiconductor packages 1 may be formed simultaneously. The molding structure 130, the image sensor chip 110, the adhesive layer 140, and the cover glass 120 may be disposed on a single semiconductor substrate 100 for each unit semiconductor package formation region S. In this state, the plurality of semiconductor packages 1 may be formed by dicing each semiconductor package 1 for each unit semiconductor package formation region S.

Although embodiments have been described with reference to the drawings, one of ordinary skill in the art may apply various technical modifications and variations based thereon. Suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents of the claims are within the scope of the following claims.

What is claimed is:

1. A semiconductor package comprising:
a semiconductor substrate;
an image sensor chip disposed on a first substrate surface of the semiconductor substrate;
a cover glass disposed spaced apart from an upper portion of the image sensor chip;
a molding structure comprising a step configured to accommodate the cover glass, wherein a side surface of the cover glass extends above the molding structure, and disposed on the first substrate surface of the semiconductor substrate to surround the image sensor chip; and
an adhesive layer disposed at a bottom surface and an inner side surface of the step and configured to fix a lower surface and the side surface of the cover glass to the molding structure.

2. The semiconductor package of claim 1, further comprising:
a conductive wire configured to electrically connect the image sensor chip to the first substrate surface,
wherein a redistribution layer (RDL) electrically connected to the conductive wire is formed in the semiconductor substrate,
wherein a connection pad electrically connected to the RDL is disposed on a second substrate surface of the semiconductor substrate, and
wherein a connection terminal electrically connectable to another semiconductor package or a motherboard is disposed in a fan-out structure on the connection pad.

3. The semiconductor package of claim 1, wherein a sum of an area of the bottom surface of the step and an area of the inner side surface of the step is greater than a cross-sectional area of the molding structure in a state in which the first substrate surface is viewed.

4. The semiconductor package of claim 1, wherein an area of the inner side surface of the step is greater than an area of an uppermost surface of the molding structure.

5. The semiconductor package of claim 1, wherein an upper edge portion of the cover glass has a bevel shape or a rounded shape.

6. The semiconductor package of claim 1, wherein
the molding structure comprises:
a wall disposed on the first substrate surface; and
a protrusion protruding upward from an outer edge portion of the wall, and
the step is formed by an upper surface of the wall and an inner side surface of the protrusion.

7. The semiconductor package of claim 6, wherein
the molding structure comprises a storage space formed in a shape recessed in at least a portion of the protrusion, and
a bottom surface of the storage space is on a same plane as the upper surface of the wall.

8. The semiconductor package of claim 7, wherein
the molding structure comprises a plurality of straight regions and a plurality of corner regions in a plan view, and
the storage space is formed on at least one straight region of the plurality of straight regions.

9. The semiconductor package of claim 8, wherein the storage space is formed at a center portion of the at least one straight region of the plurality of straight regions.

10. The semiconductor package of claim 8, wherein the storage space is not formed in the plurality of corner regions.

11. The semiconductor package of claim 1, wherein the molding structure further comprises a storage space in which an extra adhesive material of an adhesive material forming the adhesive layer remains, wherein the extra adhesive material extends from an area between the step and the cover glass.

12. The semiconductor package of claim 1, wherein a width of the cover glass is less than a width of a space between inner side surfaces of steps facing each other in a plan view.

13. The semiconductor package of claim 1, wherein the cover glass comprises:
a main glass portion supported by the step; and
a lower glass portion protruding downward from the main glass portion toward the first substrate surface and fixed to an inner side surface of the molding structure by the adhesive layer.

14. The semiconductor package of claim 1, wherein the cover glass comprises:
a main glass portion supported by the step; and
a side glass portion protruding upwardly and outwardly from an upper side of a side surface of the main glass portion and fixed to an uppermost surface of the molding structure by the adhesive layer.

15. The semiconductor package of claim 1, further comprising:
a reinforcing body disposed at a position overlapping the molding structure and the cover glass in a state in which the first substrate surface is viewed.

16. The semiconductor package of claim 1, wherein an adhesive pattern having an uneven shape is formed on at least one of the bottom surface and the inner side surface of the step.

17. A semiconductor package comprising:
a semiconductor substrate comprising a first substrate surface on which a first connection pad is exposed, a second substrate surface on which a second connection pad is exposed, and a redistribution layer (RDL) connecting the first connection pad to the second connection pad;
an image sensor chip disposed at a center portion of the first substrate surface of the semiconductor substrate and connected to the first connection pad;
a cover glass disposed spaced apart from an upper portion of the image sensor chip, having a greater area than the image sensor chip, having a center portion aligned to a center portion of the image sensor chip in a plan view;
a molding structure comprising a step configured to accommodate an edge of the cover glass and disposed on the first substrate surface of the semiconductor substrate to surround the image sensor chip;
an adhesive layer disposed at the step and configured to fix the cover glass to the molding structure;
a conductive wire configured to connect the image sensor chip to the first connection pad; and
a connection terminal connected to the second connection pad,
wherein, in a plan view, an inner side surface of the step is spaced outward and apart from a side surface of the cover glass such that the adhesive layer is disposed in a space between a bottom surface of the step and a lower surface of the cover glass and in a space between the inner side surface of the step and the side surface of the cover glass.

18. A semiconductor package manufacturing method comprising:
forming a molding structure with an upper portion of the molding structure having a step on an edge of a first substrate surface of a semiconductor substrate;
disposing an image sensor chip at a center portion of the first substrate surface; and
bonding a lower surface and a side surface of a cover glass to a bottom surface and an inner side surface of the step formed on an upper end portion of the molding structure.

19. The semiconductor package manufacturing method of claim 18, wherein the bonding of the lower surface and the side surface of the cover glass to the bottom surface and the inner side surface of the step comprises:
applying an adhesive material to the bottom surface and the inner side surface of the step; and
placing the cover glass on the adhesive material applied to the step.

20. The semiconductor package manufacturing method of claim 18, wherein the disposing of the molding structure comprises:
installing a dam structure on an inner side and an outer side of a boundary of a unit semiconductor package forming region;
forming the molding structure by injecting a molding material in an interspace of the dam structure installed on the inner side and the outer side of the boundary of the unit semiconductor package forming region; and
removing the dam structure.
